(19) United States
(12) Patent Application Publication
(10) Pub. No.: US 2004/0090820 A1
(43) Pub. Date: May 13, 2004

(54) Low standby power SRAM

(76) Inventors: Saroj Pathak, Los Altos Hills, CA (US); James E. Payne, Boulder Creek, CA (US)

Correspondence Address: SCHNECK & SCHNECK, P.O. BOX 2-E, SAN JOSE, CA, 95109-0005, US

(21) Appl. No.: 10/290,980

(22) Filed: Nov. 8, 2002

(51) Int. Cl. G11C 11/00

(52) U.S. Cl. 365/154

(57) ABSTRACT

Attaining low standby power consumption in SRAM cells by reducing the current leakage through the transistors when they are switched off. The reduction is accomplished by raising the grounding voltage of the transistors, thereby reducing the source-drain voltage differential across the transistors, and enhancing the current limiting body effect, which in turn results in leakage current reduction. The grounding voltage is raised by a diode or other current-independent voltage modification means, such as an added voltage supply.

### FIELD OF THE INVENTION

The present invention relates to semiconductor memories and, in particular, latching circuits for use with such memories.

### BACKGROUND ART

As more and more transistors are being packed into smaller and smaller semiconductor chip packages, the physical dimensions of the transistors have to be reduced. In order to maintain the desired electrical characteristics, one of the consequences of this trend is the reduction of the thickness of the gate insulator layers. However, these thinner insulators make electrical breakdown more likely. In order to prevent such breakdowns, the supply voltage has to be reduced. For instance, the supply voltage of integrated circuits built with 0.18 μm feature processes, (i.e. manufacturing processes whose highest resolution dimension, such as linewidth, is 0.18 μm) is typically about 1.8V. Because of the lower supply voltage, the threshold voltage of the transistors has to be reduced as well in order to maintain sufficient current drive. The typical threshold voltage for NMOS transistors built with a 0.18 μm process is only about 0.3V, while that of PMOS transistors is about −0.3V. Unfortunately, transistors with such small threshold voltage tend to leak disproportionably large amounts of current when they are in an off (standby) state. For applications such as those in battery powered handheld devices, such current leakage during the standby mode reduces battery life and, therefore, is undesirable.

A common practice in the industry is to implement a multiple FET threshold voltage circuit. However, such schemes require additional masking and ion implantation steps, which increase processing time and manufacturing cost, and thus are undesirable.

Vivek K. De et al., in U.S. Pat. No. 6,169,419 entitled “Method and Apparatus for Reducing Standby Leakage Current Using a Transistor Stack Effect”, teach a scheme of standby leakage current reduction wherein the stacking effect of transistors is exploited. Although such a scheme is effective in reducing leakage current, it is an inappropriate solution for memory circuits because the setup would inadvertently increase the grounding voltage of the transistors to the extent that data stored in the memory cells becomes unreadable.

Akamatsu et al., in U.S. Pat. No. 5,764,566 entitled “Static Random Access Memory Capable of Reducing Standby Power Consumption and Off-Leakage Current”, disclose the use of a transistor to cutoff the ground connection of an SRAM cell intermittently during the standby state so as to reduce the leakage current flow. The prior art invention is represented in FIG. 1. During the standby mode, the NMOS transistor 14, acting as a voltage controller, is switched off, disconnecting the virtual ground line 12 from the physical ground, making it a floating line. Subsequently, the leakage current will drive up the voltage at the virtual ground line 12, reducing the voltage differential across the source and drain of the standby transistors and increasing the threshold voltage of the NMOS transistors 16, thereby reducing the leakage current. However, if the voltage in the virtual ground line is allowed to increase beyond a certain point, it could prevent the reading of data held in the memory cell, resulting in the loss of data. Therefore, the above-mentioned patent clearly states that the voltage controlling NMOS transistor 14 must be switched on intermittently to drain off accumulated electricity, thereby preventing the voltage from reaching a point that would inhibit data read operation. In order to monitor the voltage on the virtual ground line and to control the intermittent switching, an elaborate activation circuit 16, such as the one shown in FIG. 8 and FIG. 9 of the Akamatsu et al. patent, is required. It would be desirable to have a simpler voltage control device.

It is an object of the present invention to provide an improved technique in reducing the leakage current of transistors in memory and latch circuits.

### SUMMARY OF THE INVENTION

The above objective has been met by maintaining the grounding voltage of the transistors in a memory and latch circuit at a stable and elevated voltage. This could be as simple as a diode, or a diode connected transistor or it could be a power supply with a small DC supply voltage. Since there is roughly a voltage drop of 0.7V across a typical diode, by inserting a diode between the ground supply line and the ground, it is as if the voltage at the ground supply line has been raised by a magnitude of 0.7V. This results in a dramatic reduction in leakage current without running the risk of endangering the stored memory or requiring a complex switching mechanism.

### BRIEF DESCRIPTION OF THE DRAWING

FIG. 1 is a simplified circuit diagram of the prior art, showing a voltage control means for reducing leakage current.

FIG. 2 is a circuit diagram that shows an implementation of the present invention.

FIG. 3 is a circuit diagram showing the switching state of the transistors while the SRAM is in a standby mode.

FIG. 4 is a circuit diagram showing an addition embodiment of the present invention.

FIG. 5 is a circuit diagram showing another embodiment of the present invention.

FIG. 6 is a circuit diagram showing yet another embodiment of the present invention.

FIGS. 7a and 7b are line graphs showing the reduction in current leakage for 2000 transistors by using the present invention.

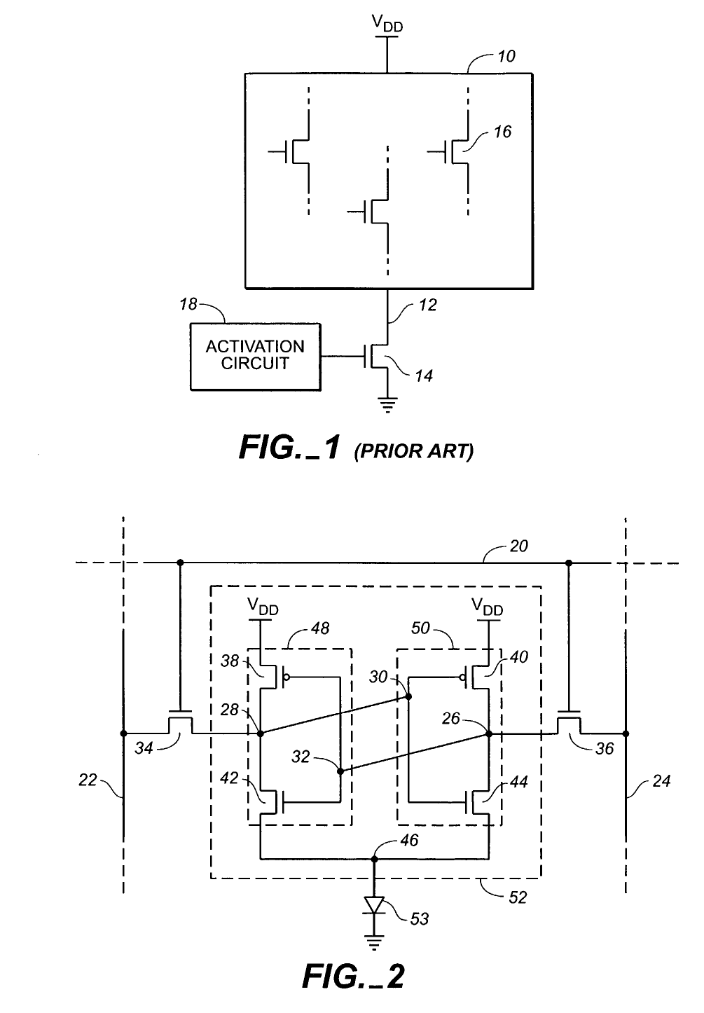

### BEST MODE FOR CARRYING OUT THE INVENTION

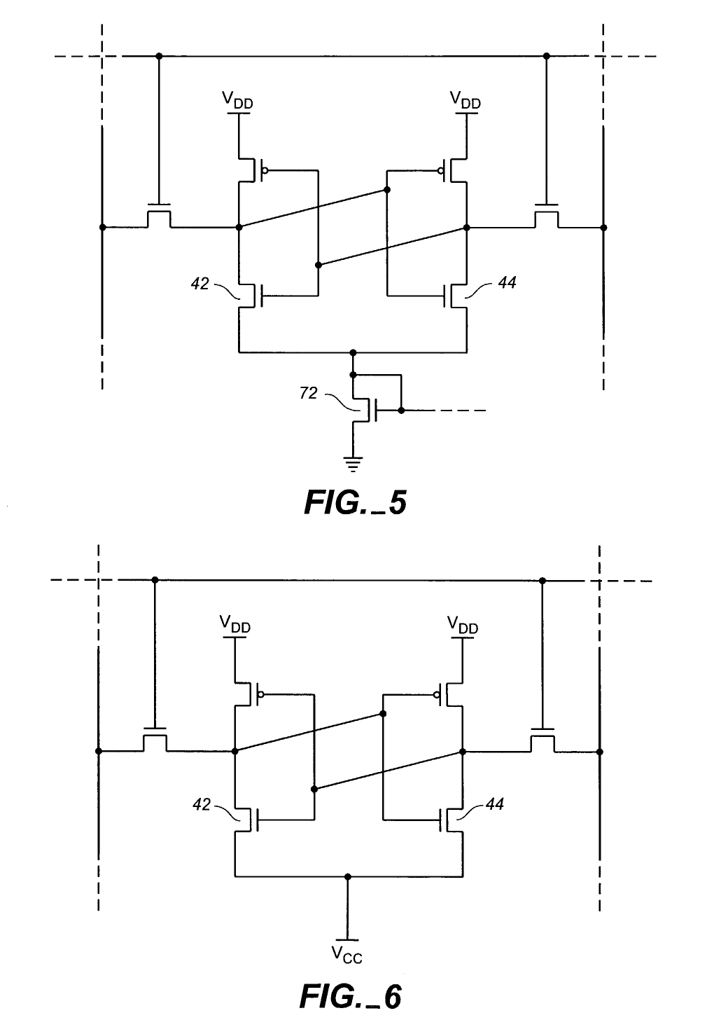

FIG. 2 shows the implementation of the present invention in a typical CMOS SRAM cell. The memory circuit shown is a flip-flop 52 comprising a first inverter 48 and a second inverter 50 cross-coupled together and a first access transistor 34 and a second access transistor 36. The first inverter 48 is made up of a PMOS transistor 38 and an NMOS transistor 42 joined together at their gates to form a first common node 32 and at their drains to form a second common node 28. The second inverter 50 is made up of a PMOS transistor 40 and an NMOS transistor 44 joined together at their gates to form a third common node 30 and at their drains to form a fourth common node 26. The second common node 32 of gates of the first inverter 48 is cross connected to the fourth common node 26 of the drains of the second inverter 50 while the third common node 30 of the gates of the second inverter 50 is cross-connected to the first common node 28 of the drains of the first inverter 48. The drain of the first access transistor 34 is connected to a first bit line 22 while the drain of the second access transistor is connected a second bit line 24 whose signal is the complement of signal in the first bit line 22. The source of the first access transistor 34 connects to the first common drain node 28 of the first inverter 48 while the source of the second access transistor 36 is connected to the fourth common drain node 26 of the second inverter 50. The gates of both access transistors 34 and 36 are connected to a word line 20. The sources of the PMOS transistors 38 and 40 are connected to power supply Vdd. In one embodiment, the sources of the NMOS transistors 42 and 44 are connected to a pn junction device such as a diode 53 shown in FIG. 2. In another embodiment shown in FIG. 5, the sources of the NMOS transistors 42, 44 are connected to a diode connected transistor 72. In another embodiment, which is shown in FIG. 6, the source of the NMOS transistors 42 and 44 are connected to a power supply whose supply voltage is set at around 0.7V. In yet another embodiment, which is shown in FIG. 4, the sources of the NMOS transistors 42 and 44 are connected to a switching device 70 which switches between a direct connection to the ground supply and a connection to the ground supply through a pn junction device depending on whether the SRAM is in active service or in standby.

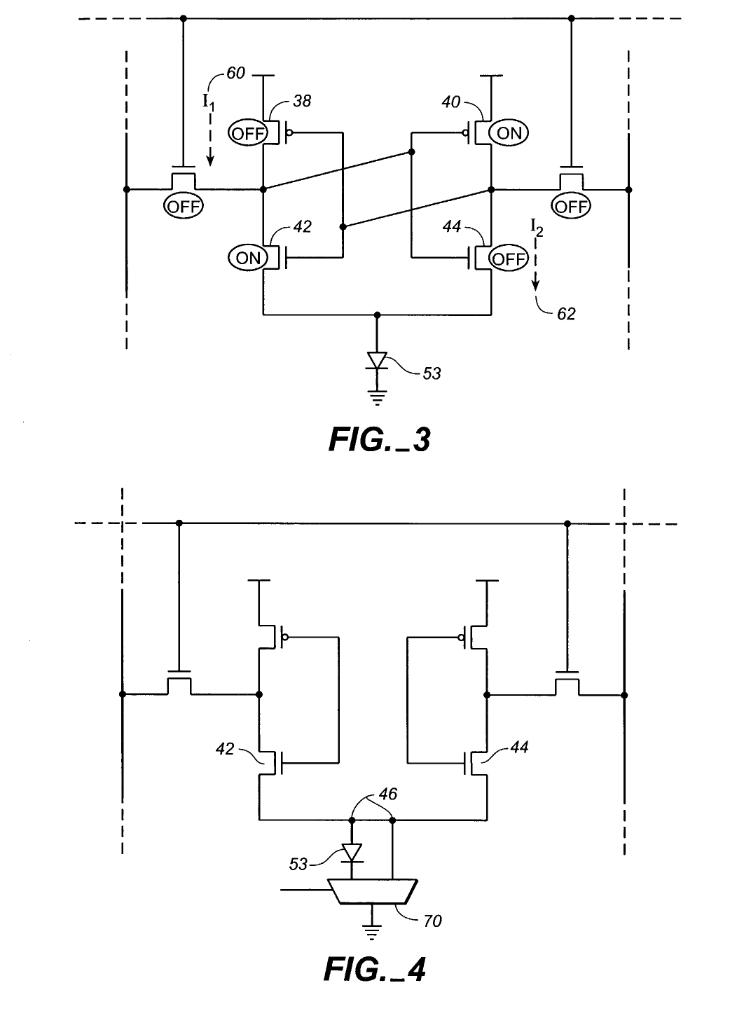

To illustrate how the addition of a diode or other current-independent voltage modifying means reduces the standby leakage current, consider the case when the memory cell is holding a 1. In such circumstance, the voltage at node 26 is high while the voltage at node 28 is low. Accordingly, the PMOS transistor 38 in the first inverter 48 is off, while the NMOS transistor 42 in the same inverter 48 is on. On the other hand, since the voltage at node 28 is low, the PMOS transistor 40 in second inverter 50 is on while the NMOS transistor 44 is off. During the standby condition, the word line 20 is deselected and thus both of the access transistors 34 and 36 are turned off. The switching states of the transistors during standby are summarized in FIG. 4. As shown in FIG. 3, there are two major leakage currents, one leakage current I₁ 60 goes through the PMOS transistor 38 in the first inverter 48 and the other leakage current 62 goes through the NMOS transistor 44 in the second inverter 50. With a diode 53 in place, the drain voltage of the PMOS transistor 38 in the first inverter 48 and the source voltage of the NMOS transistor 44 in the second inverter 50 would be raised to about 0.7V. Due to the reduction in the source-to-drain voltage in the PMOS transistor 38 and the drain-to-source voltage in the NMOS transistor 44, the leakage current is reduced. In addition, for the NMOS transistor 44, the increased voltage at the ground supply line reduces the leakage current through another mechanism known as the body effect. It arises from the fact that the substrate (body) of the NMOS transistors are typically tied to the most negative power supply, the rise of source voltage would increase the voltage difference between the source and the body (V_{sb}) of the NMOS transistor, leading to an increase in the threshold voltage Vₜ. The equation below shows the relationship between V_{sb} and Vₜ:

Vₜ=c+γ\sqrt{V_{sb}}

wherein c is a constant and γ is a device parameter that depends, among other things, on the doping of the substrate. As it is evident in the equation, the value of the threshold voltage Vₜ bears a direct proportional relation with the voltage between the source and body V_{sb}. A rise in V_{sb} increases Vₜ. The relationship between the threshold voltage Vₜ and the current through the transistor i_{D} is shown in the following equation:

$${i}_{D} = {k}_{n}^{′} \frac{W}{L} [ ( {V}_{GS} - {V}_{t} ) {V}_{DS} - \frac{1}{2} {V}_{DS}^{2} ]$$

wherein k′ₙ is the process transconductance parameter whose value is determined by the fabrication technology, W/L is the ratio of the width to length of the induced channel and it is commonly known as the aspect ratio, V_{GS} is the voltage across the gate and the source, and V_{DS} is the voltage across the drain and the source. As it is evident in the equation, the drain current i_{D} has an inverse proportional relationship with the threshold voltage Vₜ. As the threshold voltage is Vₜ is raised by an elevated V_{sb}, the leakage current i_{D} is reduced.

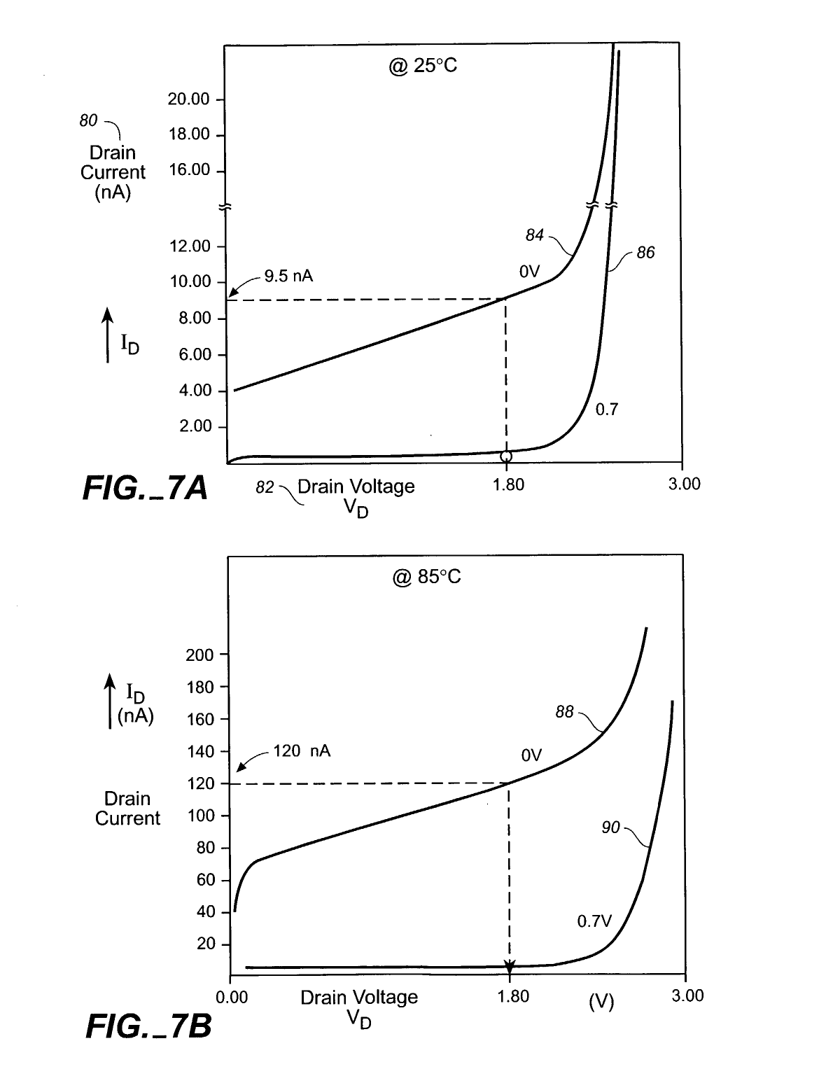

Two sets of line graphs are provided in FIG. 7 to show the dramatic reduction of leakage current by simply raising the grounding voltage of the IC by 0.7V. The graphs are plots of drain current 80, i.e. the leakage current of 0V 84, versus the drain voltage 82 at two different source voltages 0.7V 86. The leakage current in nanoamperes (na) is that of the sum total of 2000 transistors. Each of the lines 84 and 86 on the graph is generated by keeping the source at either 0V or 0.7V and then by sweeping the drain voltage 82 from 0V to 3V. As is shown in FIG. 7a, while operating at a temperature of 25 degree Celsius and at a drain voltage of 1.8V, the leakage current per 2000 transistor cells is reduced from 9.5 nA to 0.5 nA by raising the source voltage from 0V 84 to 0.7V 86. FIG. 7b shows the result at an elevated temperature of 85 degree Celsius, at which point the leakage current is reduced from 120 nA to 5 nA by raising the source voltage from 0V 88 to 0.7V 90.

As an alternative to adding a diode, one might instead connect a 0.7 VDC power supply, i.e. a current-independent voltage modifying means, to the common grounding node 46, thereby simulating the effect of having a diode. In yet another embodiment, one might choose to turn the power supply on only when the memory cell goes into standby mode. As shown in FIG. 5, similar setup could be apply to the diode connected circuit as well by connecting a switch 70 that can switch between the diode 53 and the common grounding node 46.

1. A semiconductor circuit comprising:
a data latch circuit consisting of a plurality of transistors configured in a manner so as to retain one bit of information, said data latch circuit having a power supply line connected to a first power supply and a ground supply line connected to ground through a current-independent voltage modifying means, thereby raising the effective grounding voltage to an elevated voltage.

2. The semiconductor circuit of claim 1, wherein said data latch circuit is a flip-flop.

3. The semiconductor circuit of claim 1, wherein said voltage modifying mean is a pn junction device.

4. The semiconductor circuit of claim 3, wherein said pn junction device is a diode.

5. The semiconductor circuit of claim 3, wherein said pn junction device is a diode-connected transistor, the diode arranged to provide a current-independent voltage drop.

6. The semiconductor circuit of claim 1, wherein said voltage modifying circuit is a second voltage supply having a voltage that is substantially less than the first voltage supply.

7. A semiconductor circuit comprising:
an SRAM cell having a power supply line and a ground supply line wherein the power supply line connect to a first power supply and the ground supply line can be switched, through switching means, between a connection to a ground through a current-independent voltage modifying means and a connection to the ground directly.

8. The semiconductor circuit of claim 7, wherein said SRAM cell is a flip-flop.

9. The semiconductor circuit of claim 7, wherein said voltage modifying means is a pn junction device.

10. The semiconductor circuit of claim 9, wherein said pn junction device is a diode.

11. The semiconductor circuit of claim 9, wherein said pn junction device is a diode-connected transistor, the diode arranged to provide a current-independent voltage drop.

12. The semiconductor circuit of claim 7, wherein said voltage modifying means is a second voltage supply that has a supply voltage substantially less than that of the first supply voltage.

13. The semiconductor circuit of claim 7, wherein the switching means is a 2-to-1 multiplexer that connects the ground supply line to ground though a voltage modifying means when the latch circuit goes into standby mode.

14. A semiconductor circuit comprising:
a first and second inverters, each having a signal input, a signal output, a power supply input, and a ground supply input, wherein the signal inputs and the signal outputs of the first and second inverters are cross coupled together to form a latching circuit, the power supply inputs of the first and second inverters being connected to a first power supply, the ground supply inputs of the first and second inverters being joined together to form a common node, and a steady, current-independent, voltage modifying means connected between said common node and a ground supply;
a first NMOS access transistor with its source connected to the output of the first inverter and the input of the second inverter, its drain connected to a first bit line, and its gate connected to a word line;
a second NMOS access transistor with its source connected to the input of the first inverter and the output of the second inverter, its drain connected to a second bit line which carries a complementary signal to the first bit line, and its gate connected to said word line.

15. The semiconductor circuit of claim 14, wherein the steady voltage modifying means is a pn junction device.

16. The semiconductor circuit of claim 15, wherein the steady voltage modifying means is a diode.

17. The semiconductor circuit of claim 15, wherein the steady voltage modifying means is a diode connected transistor, the diode arranged to provide a current-independent voltage drop.

18. The semiconductor circuit of claim 14, wherein said steady voltage modifying means is a second voltage supply that has a supply voltage substantially less than that of the first supply voltage.
